(19) United States
(12) Patent Application Publication
(10) Pub. No.: US 2005/0173145 A1
(43) Pub. Date: Aug. 11, 2005

(54) Electromagnetic wave shield gasket and its manufacturing method

(75) Inventors: Hiraaki Ohtsuka, Kobe-shi (JP); Haruka Saito, Kobe-shi (JP); Motoyasu Baba, Kobe-shi (JP); Shigeki Matsuoka, Kobe-shi (JP)

Correspondence Address: JORDAN AND HAMBURG LLP, 122 EAST 42ND STREET, SUITE 4000, NEW YORK, NY, 10168, US

(73) Assignee: Zippertubing Japan, Ltd., Kobe-shi (JP)

(21) Appl. No.: 11/053,165

(22) Filed: Feb. 7, 2005

(30) Foreign Application Priority Data
Feb. 10, 2004 (JP) 2004-068115
Apr. 27, 2004 (JP) 2004-162562

(51) Int. Cl. H05K 9/00

(52) U.S. Cl. 174/35 GC; 277/920

(57) ABSTRACT

Synthetic resin films 4, 4 are bonded to a thin foam sheet 2 on both sides. Numerous through-holes 5 are formed in the laminated sheet from the front to back side. A conductive coating material is applied to the surfaces of the films 4, 4 and fill the numerous through-holes 5 to form conductive layers 6, 6 on the surfaces of the films 4, 4 and numerous conductive passages 6a in the numerous through-holes 5 connected to conductive layers 6, 6. In another structure, a film and a conductive layer are formed on one side of the foam sheet, numerous conductive coating segments are formed near the openings of numerous through-holes on the back, and the conductive layer and numerous conductive coating segments are connected via numerous conductive passages.

### TECHNICAL FIELD

The present invention relates to an electromagnetic wave shield gasket for shielding electromagnetic waves generated in electronic devices and measuring instruments or undesired electromagnetic waves invading from the outside and its manufacturing method.

A variety of electromagnetic wave shield gaskets are provided on the housings of electronic devices and measuring instruments that generate electromagnetic waves and medical equipment. Such shield gaskets are often of a sheet type for space-saving as a result of the down-sized and light-weight design of electronic devices.

Prior art electromagnetic wave shield gasket sheets include a conductive sheet containing metal powders, a thin sponge-like foam with a conductive film or conductive filaments wound for electrical conductivity, the electro-less plated urethane foam described in Japanese Laid Open Patent Application Publication No. Hei 11-214886, and a porous synthetic resin sheet having woven fabric laminated on both sides and an entirely electro-less plating described in Japanese Laid Open Patent Application Publication No. Hei 11-220283.

Japanese Laid Open Patent Application Publication No. 2003-51691 discloses an electromagnetic wave shield gasket in which a conductive film having numerous pores and conductive depositions on both sides is bonded to a cushioned gasket body on one or both sides conductive layers also being formed on the walls of the pores so that the conductive film is electrically conductive between the front and rear sides.

Japanese Laid Open Patent Application Publication No. Hei 09-27695 discloses a shield tape in which numerous pores are formed in a synthetic resin film with a metal foil laminated using a sharp needle on which a deposition coating is formed, whereby both surfaces of the film are electrically conductive via the deposition coating in the numerous pores.

Japanese Laid Open Patent Application Publication No. 2000-68678 discloses an electromagnetic wave shield comprising a thin molded synthetic resin article (film or sheet) having numerous through-holes and coated with thin conductive metal film on the surfaces.

With respect to the electromagnetic wave shield gaskets disclosed in Japanese Laid Open Patent Application Publication No. Hei 11-214886 and No. Hei 11-220283, a conductive sheet containing metal powder is generally expensive and the material may lose its intrinsic resiliency (cushioning property) when filled with a conductive material. When an attempt is made to produce an extremely thin electromagnetic wave shield gasket, the gasket, which consists of a sponge-like foam with a wound conductive film or filament is extremely difficult to form because of reduced core rigidity, which problematically reduces production efficiency. Furthermore, sponge tailings, fabric fuzz, and filament fragments are generated from the materials and plated metal flakes from the plated items, possible causes of short-circuiting in a mountable electronic device.

On the other hand, the shield gasket disclosed in Japanese Laid Open Patent Application Publication No. 2003-51691 has conductivity only between the surfaces of the front conductive film or between the surfaces of the back conductive film. There is no conductive passage from one side to the other of the gasket body. Although conductivity is obtained along the surface, there is almost no conductivity through the thickness. Non-woven fabric is made conductive and used as a cushioning material for the gasket body, causing a problem that the shield gasket lacks sufficient resiliency.

The conductive tape disclosed in Japanese Laid Open Patent Application Publication No. Hei 09-27695 uses a synthetic resin film having insufficient resiliency and, because of the type of tape, is not suitable for use on the inner surface of an electronic device housing. Numerous projections are formed using a needle point after a metal foil is laminated to a film, and pores are formed in the projections by means of radiant heat or latent heat during vacuum deposition, requiring strict temperature control and complicating the production process, leading to increased production costs.

With respect to the electromagnetic wave shield product disclosed in Japanese Laid Open Patent Application Publication No. 2000-68678, a thin metal coating is formed directly on the surface of a thin molded synthetic resin article by electro-less plating. When the thin molded article comprises a foam sheet, plating solution infiltrates the foam sheet and reduces its resiliency. Moreover, it is numerically impractical for the electromagnetic wave shield product to have 10 to 50,000 pores/cm².

An objective of the present invention is to provide an electromagnetic wave shield gasket having reliable conductivity between the front and back sides and a method for producing it. Another objective of the present invention is to provide an electromagnetic wave shield gasket that ensures resiliency and produces no sponge tailings, plated metal flakes, and fuzz, which are possible causes of short-circuiting, and a method for producing it. Another purpose of the present invention is to provide an electromagnetic wave shield gasket that can be efficiently produced by an inexpensive means and a method for manufacturing it.

### SUMMARY OF THE INVENTION

The electromagnetic wave shield gasket of the present invention is an electromagnetic wave shield gasket sheet characterized by comprising a synthetic resin foam sheet having open or closed cells, a flexible synthetic resin film bonded to the foam sheet at least on one side, multiple through-holes formed through the thickness of the foam sheet and film, a conductive coating formed on the surface of the synthetic resin film, and multiple conductive passages formed in the multiple through-holes and connected at least to the conductive coating.

According to the present invention, not only is conductivity established along the surface of the conductive coating at least on one side of the electromagnetic wave shield gasket, but conductivity is also established from the conductive coating at least on one side to the other side via multiple conductive passages. Therefore, an electromagnetic wave shield gasket exerting stable and excellent electromagnetic wave shield properties and producing no sponge tailings, plated metal flakes, and fuzz, which are possible causes of short-circuiting, can be obtained.

The present invention yields the following efficacy.

The synthetic resin foam sheet itself is not filled with conductive material. Therefore, an extremely thin electromagnetic wave shield gasket that can be produced readily and efficiently at low cost is obtained without impairing the intrinsic resiliency of the material. Particularly, a synthetic resin film is bonded to the foam sheet at least on one side. A conductive coating can be formed with the cells at least on one side of the foam sheet being certainly blocked to prevent the coating material for forming the conductive coating from infiltrating into the cells at least on one side, and not impairing the resiliency.

The material, thickness, and shape of the foam sheet and synthetic resin film and the positions, distance, and diameter of the pores can be freely changed to adapt to a variety of products and high frequency electromagnetic wave shields. An electromagnetic wave shield gasket adaptable to a wide range of applications can be obtained with no restrictions on the mountable devices.

Examples of various embodiments of the present invention will be described.

(a) The synthetic resin film is bonded to the foam sheet on both sides and the conductive coatings on the surfaces of the synthetic resin films on both sides and multiple conductive passages are formed by a conductive coating layer.

In this embodiment, the films are bonded to the foam sheet on both sides and the conductive coatings are formed on their surfaces. The conductive coatings and multiple conductive passages are formed by a conductive coating layer. Therefore, an electromagnetic wave shield gasket having an excellent electromagnetic wave shield properties can be obtained and the conductive coatings and multiple conductive passages can be readily formed.

(b) The synthetic resin film is bonded to the foam sheet on one side, the conductive coating on the surface of the synthetic resin film and multiple conductive passages are formed by a conductive coating layer, multiple conductive coating segments are formed near the openings of multiple through-holes on the side of the foam sheet where no film is formed, with the multiple conductive coating segments each being connected to multiple conductive passages.

The electromagnetic wave shield gasket of this embodiment allows for reduced production cost. This gasket is suitable for use with the multiple grounded conductive coating segments.

(c) The foam sheet is made of a synthetic resin material having open cells, the synthetic resin film is bonded to the foam sheet on both sides, and the conductive coatings on the surfaces of the synthetic resin films on both sides and multiple conductive passages are formed by an electro-less plated layer.

(d) The foam sheet is made of a synthetic resin material having closed cells, in which the synthetic resin film is bonded to the foam sheet on both sides, and the conductive coatings on the surfaces of the synthetic resin films on both sides and multiple conductive passages are formed by an electro-less plated layer.

In the embodiments (c) and (d) above, the conductive coatings are formed by electro-less plating with the cells of the foam sheet on the both sides being blocked with the film. Therefore, the plating material does not infiltrate into the cells of the foam sheet, which ensures gasket resiliency.

(e) The foam sheet has a thickness of 0.1 to 5.0 mm before the thorough-holes are formed therein.

(f) The through-holes have a diameter of 0.1 to 1.5 mm and multiple through-holes are formed at a density of 2 to 100/cm².

(g) An adhesive material is applied to at least one side of the electromagnetic wave shield gasket.

The method for manufacturing the electromagnetic wave shield gasket of the present invention is characterized by comprising a first step of bonding a flexible synthetic resin film to a synthetic resin foam sheet having open or closed cells at least on one side, a second step of forming multiple through-holes through the thickness of the foam sheet and film, and a third step of forming a conductive coating on the surface of the synthetic resin film and forming multiple conductive passages in the multiple through-holes.

Using the manufacturing method above, an electromagnetic wave shield gasket having the excellent properties described above can be produced through the simple first, second, and third steps.

Examples of various embodiments of the method for manufacturing the electromagnetic wave shield gasket are described next.

(h) In the third step, a conductive coating material is applied to the surface of the synthetic resin film and multiple through-holes to form the conductive coating and multiple conductive passages.

(i) A synthetic resin foam sheet having open cells is used as the foam sheet, a flexible synthetic resin film is bonded to the foam sheet on both sides in the first step, and the surfaces of the synthetic resin films and multiple through-holes are subject to electro-less plating to form the conductive coatings and multiple conductive passages in the third step.

In this embodiment, electro-less plating is conducted after the films are bonded to the foam sheet on both sides, preventing the plating material from infiltrating into the foam sheet, producing an electromagnetic wave shield gasket having an excellent resiliency.

(i) A synthetic resin foam sheet having closed cells is used as the foam sheet, a flexible synthetic resin film is bonded to the foam sheet at least on one side in the first step, and the surface of the synthetic resin film and multiple through-holes are subject to electro-less plating to form the conductive coating and multiple conductive passages in the third step.

In this embodiment, the electro-less plating is conducted after the film is bonded to the foam sheet at least on one side, which prevents the plating material from infiltrating into the foam sheet at least from one side, producing an electromagnetic wave shield gasket having an excellent resiliency.

### BRIEF EXPLANATION OF DRAWINGS

FIG. 1 is a perspective view of an electromagnetic wave shield gasket according to Embodiment 1 of the present application,

FIG. 2 is a cross section of the electromagnetic wave shield gasket according to Embodiment 1.

FIG. 3 is a cross section of an electromagnetic wave shield gasket according to Embodiment 2.

FIG. 4 is a cross section of an electromagnetic wave shield gasket according to Embodiment 3.

### EMBODIMENT OF THE PRESENT INVENTION

Embodiments of the present invention will be described hereafter, with reference to the drawings. The electromagnetic wave shield gasket of the present invention is an electromagnetic wave shield gasket sheet characterized by comprising a synthetic resin foam sheet having open or closed cells, a flexible synthetic resin film bonded to the foam sheet at least on one side, multiple through-holes formed through the thickness of the foam sheet and film, a conductive coating formed on the surface of the synthetic resin film, and multiple conductive passages formed in the multiple through-holes and connected at least to the conductive coating.

### Embodiment 1

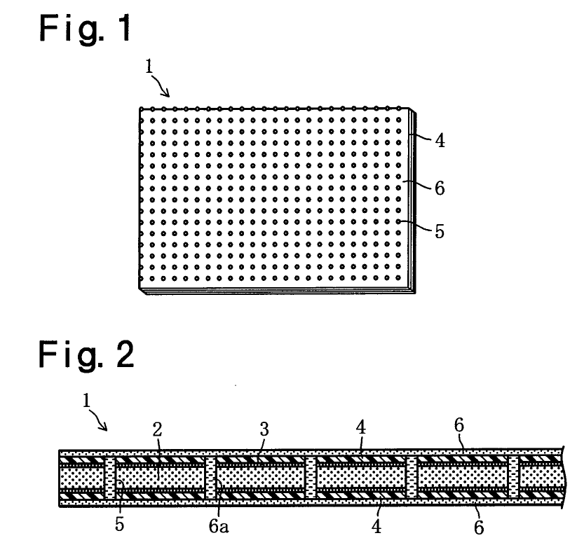

As shown in FIGS. 1 and 2, an electromagnetic wave shield gasket sheet 1 of Embodiment 1 comprises a synthetic resin foam sheet 2 having open or closed cells (continuous or independent cells), flexible synthetic resin films 4, 4 bonded to the foam sheet 2 on both sides using an adhesive material 3, numerous through-holes 5 formed through the thickness of the foam sheet 2 and films 4 on both sides, conductive layers 6, 6 (conductive coatings) formed on the surfaces of the films 4, 4 on both sides, and numerous conductive passages 6a formed in the numerous through-holes 5 and electrically connected to the conductive layers 6, 6 on both sides.

As shown in FIGS. 1 and 2, the numerous through-holes 5 are formed through the thickness of the front-side synthetic resin film 4, foam sheet 2, and back-side synthetic resin film 4. The conductive layers 6 are formed on the surfaces of the films 4, 4 on both sides. The through-holes 5 are filled with the same conductive material as that of the conductive layers 6 to form the conductive passages 6a. The conductive layers 6, 6 on both sides are electrically connected via numerous conductive passages 6a.

The synthetic resin foam sheet 2 is made of resilient foam such as polyurethane resin, polyethylene resin, and synthetic or natural rubber. The foam sheet 2 has a thickness of approximately 0.1 to 10.0 mm. It is desirable that the foam sheet 2 has a thickness of approximately 0.1 to 5.0 mm for a thin electromagnetic wave shield gasket. The through-holes 5 desirably have a diameter of approximately 0.3 to 3.0 mm and multiple through-holes 5 are desirably formed at a density of 2 to 100/cm².

The through-holes 5 are formed after the synthetic resin films 4, 4 are bonded to the foam sheet 2 as described hereafter. This is done at a lower speed to prevent irregular geometry of the through-holes 5 where the foam sheet 2 has a thickness of 2.0 mm or greater. The electromagnetic wave shield gasket may become less resilient where the foam sheet 2 has a thickness of 0.3 mm or smaller. Therefore, it is further preferred that the foam sheet 2 has a thickness of approximately 0.3 to 2.0 mm before it is made conductive.

The adhesive 3 for bonding the films 4 to the foam sheet 2 is preferably polyurethane resin, acryl resin and epoxy resin adhesives and hot melt. The flexible synthetic resin film 4 can be a polyethylene terephthalate resin, polyphenylene sulfide resin, nylon resin, or polyether sulfone resin film and preferably has a thickness of 10 to 150 μm.

The functions and advantages of the electromagnetic wave shield gasket 1 will be described hereafter. The electromagnetic wave shield gasket 1 is electrically conductive not only along the surfaces of the conductive layers 6, 6 but also between the conductive layers 6, 6 on both of the front and back sides via the multiple conductive passages 6a. Therefore, an electromagnetic wave shield gasket exerting stable and excellent electromagnetic wave shield properties and producing no sponge tailings, plated metal flakes, and fuzz, which are possible causes of short-circuiting, can be obtained.

Furthermore, the films 4, 4 bonded to the foam sheet 2 on both sides prevents the conductive material from infiltrating into the foam sheet 1 during the formation of the conductive layers 6, 6, ensuring the resiliency (cushioning property) of the foam sheet 2 and, accordingly, the resiliency of the electromagnetic wave shield gasket 1. Hence, an extremely thin electromagnetic wave shield gasket 1 that can be produced readily and efficiently with low cost can be obtained without impairing the intrinsic resiliency of the material since the foam sheet 2 is not filled with conductive material.

The material, thickness, and shape of the foam sheet 2 and films 4 and the positions, distance, and diameter of the pores can be freely changed to adapt to a variety of products and high frequency electromagnetic wave shields. An electromagnetic wave shield gasket 1 adaptable to a wide range of applications can be obtained with no restrictions on the mountable devices.

A method for manufacturing the electromagnetic wave shield gasket 1 will be described hereafter. In the first step, the foam sheet 2 and two films 4, 4 having predetermined dimensions are prepared, adhesive 3 is applied to the foam sheet 2 on both sides, and films 4, 4 are superimposed and bonded to the foam sheet 2. A laminate processing machine can be used for the bonding.

In the second step, numerous through-holes 5 are formed though the thickness of the foam sheet 2 and both films 4, 4. The through-holes 5 are generally formed by piercing from the top to bottom using multiple needle-like parts. Preheated needle-like parts can be used for more stable piercing.

In the third step, the conductive layers 6 are formed on the surfaces of the front and back films 4, 4 having the through-holes 5 formed, respectively, and numerous conductive passages 6a are formed in the numerous through-holes 5 to electrically connect the conductive layers 6, 6 on both sides.

Preferred conductive materials for forming the conductive layers 6 and conductive passages 6a include conductive coating materials containing a metal, such as silver (Ag), nickel (Ni), copper (Cu), and Aluminum (Al), or a complex of these metals and a filler for adjusting the viscosity. The conductive coating material can be applied using a roller or spraying. Meanwhile, the conductive coating material infiltrates the through-holes 5 from the front and back side and meets in the through-holes 5 to form continuous conductive passages 6a, establishing conductivity between the front and back sides. The conductive coatings preferably have a thickness of 10 to 150 μm.

Sheets having the conductive layers 6, 6 and numerous conductive passages 6a formed by the conductive coating material are dried done by natural drying, heat drying, or other known means to complete the electromagnetic wave shield gasket 1. The electromagnetic wave shield gasket 1 produced in the simple steps above has the front and back conductive layers 6, 6 that are electrically connected via numerous conductive passages 6a. Therefore, it is conductive along the surface of the conductive layer 6 and between the front and back sides.

The electromagnetic wave shield gasket 1 produced as described above is provided at predetermined positions on both or one side with a double-sided adhesive tape for attaching and fixing it to an electronic device. Alternatively, adhesive is applied to the electromagnetic wave shield gasket 1 on one side and covered with a release paper. In use, the release paper is peeled off and the adhesive is used to attach the electromagnetic wave shield gasket 1 to an electronic device.

Experiments and their results will be described hereafter in which multiple different electromagnetic wave shield gaskets 1 have actually been produced and their conductivity evaluated. The foam sheet 2 is made of soft polyurethane resin foam having a thickness of 0.5 mm. Polyphenylene sulfide resin films 4 having a thickness of 12 μm were superimposed and bonded to the foam sheet 2 on both sides using a polyurethane resin adhesive, after which numerous through-holes 5 having a diameter of 1.2 mm were formed in the laminated sheet by piercing from the front to back side at intervals of 4.8 mm in the X,Y directions.

Conductive coating materials for forming conductive layers on the front and back sides of the laminated sheet having the numerous through-holes 5 formed were prepared by evenly mixing Tie-force AD-865HV made by Dai-Nippon Ink (urethane resin-based, the resin content=50%), silver powder (the average particle size=6 μm), and ethyl acetate as an organic solvent for adjusting the viscosity at the ratios shown in Table 1. The conductive coating material has a viscosity of 4000 mPa·s, the conductive coating materials being applied to the laminated sheet on both sides to fill the numerous through-holes 5. The coatings had a thickness of 20 to 25 μm after being dried.

The electric resistance, which is an index of the electromagnetic wave shield properties, of the electromagnetic wave shield gaskets 1 produced as described above was measured. The electric resistance along the surface and through the thickness was measured. Roresta MCP-T600 made by Mitsubishi Chemistry was used for measuring the electric resistance along the surface.

For measuring the electric resistance through the thickness, two 25 mm×25 mm brass conductor pieces were respectively superimposed on the electromagnetic wave shield gasket fragment on the front and back sides. Electrical resistance between the two brass conductor pieces was measured with a specific load being imposed through the thickness of the gasket. Milliohm High tester 3450 made by Hioki Electric Appliances was used to measure the electric resistance. The results are given in Table 1.

TABLE 1

| | content | | electric | electric resistance *2 | | |
|---|---|---|---|---|---|---|
| | (weight %) | | resistance *1 | (through the thickness) | | |
| experiment | | silver | (along the | 100 g | 500 g | 1000 g |
| No. | resin | powder | surface) | load | load | load |
| 1 | 20 | 80 | 0.2 | 0.07 | 0.04 | 0.02 |
| 2 | 25 | 75 | 0.3 | 0.2 | 0.08 | 0.06 |
| 3 | 30 | 70 | 0.9 | 0.4 | 0.1 | 0.08 |
| 4 | 35 | 65 | 3.0 | 0.8 | 0.3 | 0.2 |
| 5 | 40 | 60 | 8.0 | 1.1 | 0.7 | 0.5 |

[Note]
*1 unit: Ω / □
*2 unit: Ω / 25 mm SQ

The experimental results given in Table 1 above show that lower resistance is obtained when the silver powder content in the conductive coating material was 70% or higher, promising the efficacy of the electromagnetic wave shield gaskets.

### Embodiment 2

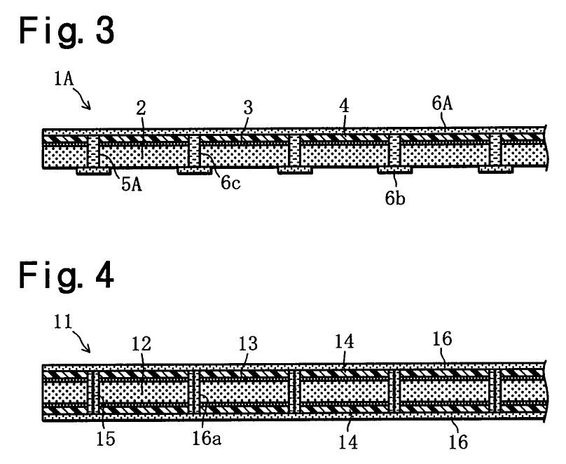

FIG. 3 shows an electromagnetic wave shield gasket 1A, according to Embodiment 2, in which the same components are given the same reference numerals as in the electromagnetic wave shield gasket 1 of the embodiment described above. The electromagnetic wave shield gasket 1A has a similar perspective view to that of FIG. 1.

The electromagnetic wave shield gasket 1A comprises a resilient synthetic resin foam sheet 2 having open or closed cells, a flexible synthetic resin film 4 bonded to the foam sheet 2 on one side using an adhesive 3, numerous through-holes 5 formed through the thickness of the foam sheet 2 and film 4, a conductive layer 6A (conductive coating) formed on the surface of the synthetic resin film 4, numerous conductive coating segments 6b formed near the openings of the multiple through-holes 5A on the side of the foam sheet 2 where there is no film 4, and multiple conductive passages 6c formed in the numerous through-holes 5A and electrically connecting the conductive layer 6A to the multiple conductive coating segments 6b. The materials of resilient synthetic resin foam sheet 2, adhesive 3, and synthetic resin film 4, bonding means, and through-holes 5A are similar to those of Embodiment 1.

The functions and advantages of the electromagnetic wave shield gasket 1A will be described hereafter. The electromagnetic wave shield gasket 1A exerts basically the same functions and advantages as the electromagnetic wave shied gasket 1 of Embodiment 1 although it has the film 4 and conductive layer 6A only on one side. The electromagnetic wave shield gasket 1A can reduce production costs because it has the film 4 and conductive layer 6A only on one side. The electromagnetic wave shield gasket 1A is suitable for use with the grounded multiple conductive coating segments 6b.

A method for manufacturing the electromagnetic wave shield gasket 1A will be described hereafter. In the first step, the foam sheet 2 and film 4 are prepared and the synthetic resin film 4 is bonded to the foam sheet 2 on one side using the adhesive 3. In the second step, numerous through-holes 5 are formed though the thickness of the foam sheet 2 and film 4. In the third step, the conductive layer 6A on the surface of the film 4, numerous conductive coating segments 6c near the openings of the numerous through-holes 5A on the surface of the foam sheet 2 where there is no film 4 (on the back), and numerous conductive passages 6c in the numerous through-holes to electrically connect the conductive layer 6A to numerous conductive coating segments 6b are formed.

The conductive layer 6A, numerous conductive coating segments 6b, and numerous conductive passages 6c can be formed by applying a conductive coating material in a similar manner to Embodiment 1. In this case, the conductive coating material passes through the through-holes 5A from the front to back side to form continuous conductive passages 6c in the through-holes 5A. The conductive material overflows and forms numerous conductive coating segments 6b near the openings of the through-holes 5A on the back.

The conductive layer 6A and numerous conductive coating segments 6b are electrically connected via numerous conductive passages 6c, establishing the conductivity between the front and back sides. In addition, the numerous conductive coating segments 6b create numerous contacts on the back. The electromagnetic wave shield gasket 1A is complete with the application and drying of the conductive coating material. The drying can be done in a manner similar to that of Embodiment 1. The conductive coating preferably has a thickness of 10 to 150 μm.

With the front and back being electrically connected via the numerous conductive passages 6c in the numerous through-holes 5A, the electromagnetic wave shield gasket 1A is conductive along the surface of the conductive layer 6A and through the thickness. The electromagnetic wave shield gasket 1A can be easily coupled to the ground via the numerous conductive coating segments 6b on the back, reducing production costs.

Experiments and their results will be described hereafter in which multiple different electromagnetic wave shield gaskets 1A are actually produced and their conductivity evaluated.

The same foam sheet 2, film 4, adhesive 3, and conductive coating material were used as in Embodiment 1. However, the conductive coating material supplied from the front of the foam sheet 2 overflowed through the numerous through-holes 5A and partly adhered to the back of the foam sheet 2, forming numerous conductive coating segments 6b.

The electric resistance, which is an index of the electromagnetic wave shied property, of the electromagnetic wave shield gaskets 1A produced as described above was measured in the same manner as in Embodiment 1. The electric resistances along the surface and through the thickness were measured in the same manner as in Embodiment 1. The results are given in Table 2.

TABLE 2

| | content | | electric | electric resistance *2 | | |
|---|---|---|---|---|---|---|
| | (weight %) | | resistance *1 | (through the thickness) | | |
| experiment | | silver | (along the | 100 g | 500 g | 1000 g |
| No. | resin | powder | front surface) | load | load | load |
| 1 | 20 | 80 | 0.2 | 0.1 | 0.07 | 0.04 |
| 2 | 25 | 75 | 0.3 | 0.3 | 0.1 | 0.08 |
| 3 | 30 | 70 | 0.9 | 0.5 | 0.2 | 0.2 |
| 4 | 35 | 65 | 3.0 | 1.0 | 0.3 | 0.3 |
| 5 | 40 | 60 | 8.0 | 1.3 | 0.8 | 0.6 |

[Note]
*1 unit: Ω / □
*2 unit: Ω / 25 mm SQ

The experimental results given in Table 2 show that lower resistances were obtained when the silver powder content in the conductive coating material is 70% or higher, promising the efficacy of the electromagnetic wave shield gasket. In the electromagnetic wave shield gaskets 1A of this experiment, the conductive coating material was applied to the laminated sheet only on one side. However, they showed no significant differences from the electromagnetic wave shield gaskets 1 to which the conductive coating material was applied on both sides.

Embodiment 2 used a conductive coating material as the conductive material for forming the conductive layer 6A. Alternatively, plating materials for electro-less plating can be used to form the conductive layer 6A, conductive coating segments 6b, and conductive passages 6c. Further, conductive materials for metal deposition can be used to form the conductive layer 6A, conductive coating segments 6b, and conductive passages 6c depending on the component materials and shape of the electromagnetic wave shield gasket 1A.

### Embodiment 3

FIG. 4 shows an electromagnetic wave shied gasket sheet 11 according to Embodiment 3. The electromagnetic wave shied gasket sheet 11 has a similar perspective view to FIG. 1.

The electromagnetic wave shield gasket sheet 11 comprises a resilient synthetic resin foam sheet 12 having open or closed cells, flexible synthetic resin films 14, 14 bonded to the foam sheet 12 on both sides using an adhesive material 13, numerous through-holes 15 formed through the thickness of the foam sheet 12 and films 14, 14 conductive layers (conductive coatings) 16, 16 formed on the surfaces of both films 14, 14 and numerous conductive passages 16a formed in the numerous through-holes 5 and electrically connecting both of the conductive layers 16, 16.

The synthetic resin foam sheet 12 is made by slicing a resilient foam block. The synthetic resin foam sheet 12 is made of a synthetic resin or a synthetic or natural rubber, which is selected from, for example, urethane resin, ethylene resin, acryl resin, styrene resin, chlorinated polyethylene rubber, butyl rubber, isoprene rubber, NBR rubber, EPDM rubber, SBR rubber, Hypalon rubber, butadiene rubber, and acryl rubber.

The foam sheet 12 preferably has a thickness of approximately 0.3 to 3.0 mm. The foam sheet 12 may have open or closed cells. The adhesive material 13 can be a solvent, emulsion, or hot melt type urethane resin, polyester resin, acryl resin, or epoxy resin adhesive.

The synthetic resin material for forming the film 14 can be selected from polyethylene terephthalate resin, nylon resin, polyphenylene sulfide resin, polyether sulfone resin, acryl resin, vinyl chloride resin, and polyca resin. The film 14 preferably has a thickness of 10 to 150 μm. However, a synthetic resin coating solution can be applied to form an easily extendable coating in place of the adhesive material 13 and films 14, 14.

When the foam sheet 12 has open cells, anti-impregnating films 14 have to be bonded to the foam sheet 12 on both sides in order to prevent the plating solution from infiltrating into the cells of the foam sheet 12 during the plating described later, which otherwise causes the consumption of a large quantity of metal components in the plating solution and impairs resiliency and flexibility of the completed electromagnetic wave shield gasket. Such films 14 are necessary because the plating solution infiltrates into the fine gaps by capillary phenomenon even under highly compressed conditions.

It is preferable to bond the films 14 to the foam sheet 12 on both sides even when the foam sheet 12 has closed cells. However, the plating solution infiltrates into only part of the cells of the foam sheet 12 when the foam sheet 12 has closed cells. Therefore, a synthetic resin coating solution can be applied to form an easily extendable coating in place of the film 14 as far as the strength of the foam sheet 12 is taken into account.

The electromagnetic wave shield gasket 11 yields basically the same functions and advantages as the electromagnetic wave shield gasket 1 of Embodiment 1. However, the films 14, 14 are bonded to the foam sheet 12 on both sides before the conductive layers 16, 16 are formed; thus, the gasket 11 sustains the resiliency. In addition, the conductive layers 16, 16 and numerous conductive passages 16a are made of a plating material (a plated layer); thus, excellent conductivity is obtained.

A method for producing the electromagnetic wave gasket 11 described above will be described hereafter.

In the first step, the foam sheet 12 and films 14, 14 having predetermined dimensions are prepared and the films 14, 14 are superimposed and bonded to the foam sheet 12 on both sides using an adhesive 13. A laminate processing machine can be used for the bonding. If the foam sheet 12 has hard and less extendable films 14 bonded on both sides, fine wrinkles may appear and disrupt electric conductivity when the sheet is rolled. Therefore, it is preferred that the foam sheet 12 has a hard and less extendable film 14 on one side and a soft and more extendable film 14 on the other.

In the second step, the laminated sheet consisting of the foam sheet 12 and the films 14, 14 bonded thereto is pierced from the front to back side to form numerous through-holes 15. The through-holes 15 are formed by melting and piercing the laminated sheet through the thickness from the top to bottom of FIG. 4 using multiple preheated needle-like parts. The needle-like parts are heated to approximately 250° C. or higher although the temperature is varied depending on the melting temperatures and thicknesses of the foam sheet 12 and films 14, 14. Other piercing means include a piercing machine in which a dice having multiple needle-like punching and multiple corresponding pores is mounted on a press machine.

When the through-holes 15 are formed using heated needle-like parts, the through-holes 15 do not close as a result of elastic behavior, which is observed with the through-holes mechanically formed by, for example, a piercing machine, and they have a uniform diameter nearly equal to the needle diameter. The cells melt and close to smoothness on the inner walls of the through-holes. This can reduce the infiltration of the plating solution during electro-less plating and, accordingly, significantly reduce the consumption of the plating solution particularly when the foam sheet 2 has open cells.

Projections may easily appear on the top surface, where the needle-like parts enter, and the other, bottom surface when the through-holes 14 are formed. Films 14 that are different in hardness can be bonded to the foam sheet 12 on both sides and the through-holes are formed from the harder film 14 to the softer film 14. This way, the projections of the through-holes 15 become smaller, ensuring a smoother surface.

The multiple through-holes 15 formed in the laminated sheet preferably have a diameter that allows the plating solution to sufficiently infiltrate during the subsequent plating process. However, excessively large diameters result in a smaller number of through-holes per unit area, which will reduce the conductivity through the thickness and the strength. Repeated experiments showed an applicable diameter of the through-holes is preferably 0.1 to 1.5 mm and more preferably 0.3 to 1.0 mm.

Numerous through-holes 15 can be formed at a density of approximately 100/cm². The electromagnetic wave shield gasket 11 can have an electric resistance between the front and back sides of 1 Ω or lower with a through-hole density of at least 2/cm² or higher. Furthermore, it was found that a preferable electric resistance of 0.1 Ω or lower can be obtained with a through-hole density of 6/cm² or higher. The through-holes 15 can have a circular, square, or other opening shape as appropriate. Numerous through-holes 15 are arranged in double crosses, zigzags, or others. In any case, an uniform arrangement is preferred.

Then, in the third step, the conductive layers 16, 16 on the surfaces of the films 14, 14 and numerous conductive passages 16a are formed. This is done by electro-less plating (non-electrolytic plating) the laminated sheet having numerous through-holes 15 formed. Suitable plating baths include copper (Cu), nickel (Ni), silver (Ag), and gold (Au). These metals are used for single-layer or multilayer plating. For example, for multilayer plating, it is desired to copper plate at the bottom and nickel plate at the top. The plated layer has a thickness of approximately 0.1 to 10 μm and preferably 1 to 5 am. For multilayer plating, electrolytic plating can be used for the second and subsequent layers. Metal deposition can be used to form the conductive layers 16, 16 and conductive passages 16a depending on the component materials and shape of the electromagnetic wave shield gasket.

Experiments and their results will be described hereafter in which multiple different electromagnetic wave shield gaskets 11 were produced and their conductivities were evaluated.

The foam sheet 12 was made of soft urethane resin foam having open cells and a thickness of 0.5 mm. A 12μ polyethylene terephthalate film (a film 14) was bonded to the foam sheet 12 on one side and a 30μ urethane resin film (a film 14) on the other side via a urethane adhesive, respectively. Then, the surface of the polyethylene terephthalate film to be plated was matted in order to improve metal adhesion in electro-less plating described later.

The laminated sheet was pierced using multiple parallel hot needles having a diameter of 0.62 mm and pre-heated to 300° C. at through-hole intervals of 4.48 mm×2.6 mm from the polyethylene terephthalate film laminated side to the urethane resin film laminated side to form numerous through-holes 15.

Then, in preparation of electro-less plating, the laminated sheet having the through-holes 15 formed was treated in caustic soda (20 g/L) at 40° C. for 5 minutes to make it hydrophilic. After rinsing with water, the sheet was treated with hydrochloric acid solution (10%) for neutralization and, then, immersed in a catalytic solution containing tin chloride (2 g/L), palladium chloride (0.2 g/L), and hydrochloric acid at room temperature for catalytic treatment. After further rinsing with water, the foam resin activated in sulfuric acid solution (5%) was immersed in the electro-less plating bath below (plating bath 1) at 45° C. for 5 minutes for electro-less plating.

plating bath 1

| | |
|---|---|
| copper sulfide pentahydrate | 10 g/L |
| formaldehyde (37%) | 10 g/L |
| ethylenediamine tetraacetic acid (EDTA) | 40 g/L |
| potassium sodium tartrate | 5 g/L |
| caustic soda | 12 g/L |

Then, the sheet was immersed first in a catalytic solution containing palladium chloride (0.2 g/L) and hydrochloric acid (100 ml/L) for 2 minutes for catalytic treatment and then in the electro-less nickel plateing bath below (plating bath 2) at 60° C. for 3 minutes for electro-less nickel plating, and then dried to produce an electromagnetic wave shield gasket.

plating bath 2

| nickel sulfide hexahydrate | 20 g/L |
|---|---|
| sodium hypophosphite monohydrate | 30 g/L |
| sodium acetate | 5 g/L |
| trisodium citrate | 30 g/L |
| pH | 4.8 |

Table 3 gives the electric resistances measured to prove the conductivity between the front and back sides of the electromagnetic wave shield gaskets 11 obtained by the process above.

TABLE 3

| number of through-holes | electric resistance |
|---|---|
| (per cm²) | (Ω) |
| 1 | 3.10 |
| 2 | 0.75 |
| 3 | 0.33 |
| 4 | 0.19 |
| 5 | 0.12 |
| 6 | 0.08 |
| 7 | 0.06 |
| 8 | 0.05 |

The results show that the electromagnetic wave shield gasket 11 of the present invention had an electric resistance of lower than 1 Ω when the through-holes 15 were formed at a density of 2/cm² or higher and an electric resistance of lower than 0.1 Ω when at a density of 6/cm² or higher; practically problem-free electric resistances were obtained.

The electromagnetic wave shield gasket can be constituted in the following manner: the synthetic resin film described above is bonded to a synthetic resin sheet having open or closed cells on one side and a conductive layer (conductive coating) consisting of an electro-less plated layer is formed on the surface of the film, and numerous conductive passages are connected to the conductive layer on the one side.

### Industrial Applicability

The electromagnetic wave shield gasket of the present invention can be used in a wide range of devices while allowing for space-saving, in order to block internally produced electromagnetic waves and undesired electromagnetic waves entering from outside, such devices including electronic devices and measuring equipment where electromagnetic waves should be blocked.

1. An electromagnetic wave shield gasket sheet comprising:
a synthetic resin foam sheet having open or closed calls;
a flexible synthetic resin film bonded to said foam sheet at least on one side;
multiple through-holes formed through the thickness of said foam sheet and film;
a conductive coating formed on the surface of said synthetic resin film; and
multiple conductive passages formed in said multiple through-holes and connected at least to said conductive coating.

2. The electromagnetic wave shield gasket sheet according to claim 1 wherein
said synthetic resin film is bonded to said foam sheet on both sides and said conductive coatings on the surfaces of both of said synthetic resin films and multiple conductive passages are made of a conductive coating material.

3. The electromagnetic wave shield gasket sheet according to claim 1 wherein
said synthetic resin film is bonded to said foam sheet on one side and said conductive coating on the surface of said synthetic resin film and multiple conductive passages are made of a conductive coating material; and
multiple conductive coating segments are formed near the openings of said multiple through-holes on the side of said foam sheet where said film is absent and said multiple conductive coating segments are each connected to said multiple conductive passages.

4. The electromagnetic wave shield gasket sheet according to claim 1 wherein
said foam sheet is made of a synthetic resin material having open cells, said synthetic resin film is bonded to the foam sheet on both sides, and said conductive coating on the surfaces of both of said synthetic resin films and multiple conductive passages are made of an electro-less plated layer.

5. The electromagnetic wave shield gasket sheet according to claim 1 wherein
said foam sheet is made of a synthetic resin material having closed cells, said synthetic resin film is bonded to said foam sheet on both sides, and said conductive coatings on the surfaces of both of said synthetic resin films and multiple conductive passages are made of an electro-less plated layer.

6. The electromagnetic wave shield gasket sheet according to claim 1 wherein
said foam sheet has a thickness of 0.1 to 5.0 mm before said through-holes are formed therein.

7. The electromagnetic wave shield gasket sheet according to claim 6 wherein
said through-holes have a diameter of 0.1 to 1.5 mm and multiple through-holes are formed at a density of 2 to 100/cm².

8. The electromagnetic wave shield gasket sheet according to claim 6 wherein
an adhesive material is applied to said electromagnetic wave shield gasket at least on one side.

9. A method for manufacturing an electromagnetic wave shield gasket sheet comprising:
a first step of bonding a flexible synthetic resin film to a synthetic resin foam sheet having open or closed cells at least on one side;
a second step of forming multiple through-holes through the thickness of said foam sheet and film; and
a third step of forming a conductive coating on the surface of said synthetic resin film and forming multiple conductive passages in said multiple through-holes.

10. The method for manufacturing an electromagnetic wave shield gasket sheet according to claim 9 wherein
a conductive coating material is applied to the surface of said synthetic resin film and multiple through-holes to form said conductive coating and multiple conductive passages in said third step.

11. The method for manufacturing an electromagnetic wave shield gasket sheet according to claim 9 wherein
a synthetic resin foam sheet having open cells is used as said foam sheet, a flexible synthetic resin film is bonded to said foam sheet on both sides in said first step, and the surfaces of said synthetic resin films and multiple through-holes are subject to electro-less plating to form said conductive layer and multiple conductive passages in said third step.

12. The method for manufacturing an electromagnetic wave shield gasket sheet according to claim 9 wherein
a synthetic resin foam sheet having closed cells is used as said foam sheet, a flexible synthetic resin film is bonded to said foam sheet at least on one side in said first step, and the surfaces of said synthetic resin films and multiple through-holes are subject to electro-less plating to form said conductive layer and multiple conductive passages in said third step.
